(19) United States
(12) Patent Application Publication
(10) Pub. No.: US 2020/0006703 A1
(43) Pub. Date: Jan. 2, 2020

(54) DISPLAY PANELS, DISPLAY TERMINALS AND DISPLAY MOTHERBOARDS

(71) Applicant: Yungu (Gu'an) Technology Co., Ltd., Langfang (CN)

(72) Inventors: Li ZHANG, Langfang (CN); Bingbing SUN, Langfang (CN); Min HU, Langfang (CN); Yaqin CHAI, Langfang (CN)

(21) Appl. No.: 16/565,506

(22) Filed: Sep. 10, 2019

Related U.S. Application Data
(63) Continuation of application No. PCT/CN2018/116525, filed on Nov. 20, 2018.

(30) Foreign Application Priority Data
May 14, 2018 (CN) 201820714843.1
May 14, 2018 (CN) 201820722043.4

(51) Int. Cl. H01L 51/52; H01L 27/32

(52) U.S. Cl. CPC H01L 51/5253; H01L 2251/558; H01L 2251/301; H01L 27/3246

(57) ABSTRACT

A display panel, a display terminal and a display motherboard are provided. The display panel includes a pixel defining layer, an inorganic barrier layer, an organic light-emitting material layer, and a thin film encapsulation structure. The pixel defining layer is provided with a plurality of openings distributed in an array. The inorganic barrier layer is disposed in a part of the openings at a periphery of the pixel defining layer, and has a plurality of first grooves spaced apart on a side thereof. The organic light-emitting material layer is disposed in the part of the openings and formed on the inorganic barrier layer. The thin film encapsulation structure is disposed on the pixel defining layer, and the thin film encapsulation structure is filled in the first grooves and covers the organic light-emitting material layer.

### CROSS REFERENCE TO RELATED APPLICATIONS

This application is a continuation application for International Application No. PCT/CN2018/116525, filed on Nov. 20, 2018, which claims priority to Chinese Patent Application No. 201820722043.4, titled “DISPLAY PANEL AND DISPLAY TERMINAL” and filed on May 14, 2018, and Chinese Patent Application No. 201820714843.1, titled “DISPLAY MOTHERBOARD” and filed on May 14, 2018. The entireties of these applications are incorporated by reference herein for all purposes.

### TECHNICAL FIELD

The present disclosure relates to display technologies.

### BACKGROUND

In conventional display panels, an organic light-emitting diode (OLED) device is generally encapsulated by a thin film encapsulation structure. An inorganic layer of the thin film encapsulation structure has high compactness and can be used to block water and oxygen intrusion. Unfortunately, these conventional OLEDS structures are inadequate.

### SUMMARY

According to various embodiments of the present disclosure, a display panel, a display terminal, and a display motherboard are provided.

A display panel includes: a pixel defining layer, provided with a plurality of openings arranged in an array; an inorganic barrier layer, disposed in a part of the openings at a periphery of the pixel defining layer, and provided with a plurality of first grooves spaced apart on a side of the inorganic barrier layer; an organic light-emitting material layer, disposed in the part of the openings having the inorganic barrier layer, and formed on the inorganic barrier layer; and a thin film encapsulation structure, disposed on the pixel defining layer, the thin film encapsulation structure being filled in the first grooves and covering the organic light-emitting material layer.

A display terminal includes the above display panel.

A display motherboard includes a bearing substrate and a plurality of arrangement units formed on the bearing substrate in an array. Each arrangement unit defines an annular cutting line. The arrangement unit includes a display panel area located within the cutting line and a cutting area located outside the cutting line. The display panel area includes a display area and a non-display area located around the display area. An edge of the non-display area close to the cutting line is provided with a barrier bank. The cutting area is provided with a stress dispersion bank.

Details of one or more embodiments of the present disclosure are set forth in the accompanying drawings and description below. Other features, objects, and advantages of the disclosure will be apparent from the description and appended claims.

### BRIEF DESCRIPTION OF THE DRAWINGS

In order to more clearly illustrate the technical solutions in the embodiments of the present disclosure, the drawings to be used in the embodiments will be briefly described below. Obviously, the drawings in the following description are only some embodiments of the present disclosure. Those skilled in the art can also obtain other drawings based on these drawings without any creative work.

FIG. 1 is a schematic diagram illustrating a longitudinal section of a display panel according to an embodiment.

FIG. 2 is a top view illustrating a display motherboard according to an embodiment.

FIG. 3 is a top view illustrating an arrangement unit of FIG. 2.

FIG. 4 is a schematic diagram illustrating a longitudinal section taken along line A-A′ of FIG. 2.

FIG. 5 is a schematic diagram illustrating a longitudinal section of an arrangement unit according to another embodiment.

FIG. 6 is a schematic diagram illustrating a longitudinal section of an arrangement unit according to another embodiment.

FIG. 7 is a top view illustrating an arrangement unit according to another embodiment.

### DETAILED DESCRIPTION OF THE EMBODIMENTS

As mentioned above, conventional OLED devices utilize encapsulation structures. However, the inorganic film layer of the thin film encapsulation structure is not in close contact with an organic light-emitting material evaporated on an anode of the device, and the gap between the contact surfaces is liable to cause water and oxygen intrusion. Therefore, a pixel defining layer of the thin film encapsulation structure is prone to the problem of encapsulation failure such as water and oxygen intrusion which in turn causes damage to the OLED device, thereby affecting the service life of the display panel.

In addition, the thin film encapsulation technique is generally used in the flexible display panel. The manufacturing process of the display panel generally includes cutting display panels arranged on the display motherboard in an array. In order to obtain a specially shaped display panel, it is usually necessary to perform cutting again. However, during the cutting process, the film encapsulation structure is easily damaged, which affects the reliability of the film encapsulation.

In order to facilitate the understanding of the present disclosure, a more comprehensive description of the present disclosure will be given below with reference to the accompanying drawings. Preferred embodiments of the present disclosure are shown in the accompanying drawings. However, the disclosure can be embodied in many different forms and is not limited to the embodiments described herein. Rather, these embodiments are provided so that the understanding of the present disclosure will be understood thoroughly and comprehensively.

It should be noted that when an element is referred to as being “fixed” to another element, it may be directly on the other element or intervening elements may be present. When an element is considered to be “connected” to another element, it can be directly connected to the other element or intervening elements may be present.

Unless otherwise defined, all technical and scientific terms used herein have the same meaning as commonly understood by a skilled person in the art to which the present disclosure belongs. The terminologies used herein are for the purpose of describing particular embodiments only, and are not intended to be limiting. The term “and/or” as used herein includes any and all combinations of one or more of the associated listed items.

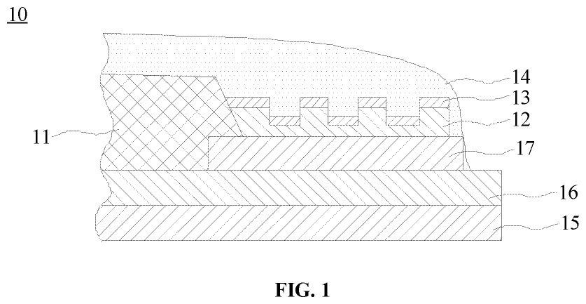

Referring to FIG. 1, a display panel 10 according to an embodiment includes a pixel defining layer 11, an inorganic barrier layer 12, an organic light-emitting material layer 13, and a thin film encapsulation structure 14. The pixel defining layer 11 is provided with a plurality of openings (not shown) distributed in an array. The inorganic barrier layer 12 is disposed in a part of the openings at a periphery of the pixel defining layer 11. The organic light-emitting material layer 13 is disposed in the part of the openings having the inorganic barrier layer 12 and formed on the inorganic barrier layer 12. A plurality of spaced apart first grooves are disposed on a side of the inorganic barrier layer 12 facing toward the organic light-emitting material layer 13. The thin film encapsulation structure 14 is disposed on the pixel defining layer 11. The thin film encapsulation structure 14 is filled in the first grooves and covers the organic light-emitting material layer 13. Specifically, the thin film encapsulation structure 14 is disposed on a surface of the organic light-emitting material layer 13 facing away from the inorganic barrier layer 12.

It can be understood that the part of the openings at the periphery of the pixel defining layer 11 are generally used to arrange pixels, i.e., to form an organic light-emitting unit for display.

In the display panel 10, the part of the openings at the periphery of the pixel defining layer 11 are provided, the inorganic barrier layer 12 having a water-oxygen barrier property superior to that of the organic light-emitting material layer 13 is disposed in the part of the openings, and the plurality of spaced apart first grooves are disposed on the side of the inorganic barrier layer 12 facing toward the organic light-emitting material layer 13 to form a concave-convex structure. And the concave-convex structure is encapsulated by the thin film encapsulation structure 14. The tightness of contact between the organic light-emitting material layer 13 and the inorganic barrier layer 12 and between the organic light-emitting material layer 13 and the inorganic layer of the thin film encapsulation structure 14 is increased, the distance and difficulty of water oxygen intrusion into the interior of the OLED device are increased, and the water and oxygen barrier property is improved. The reliability of the encapsulation and the service life of the display panel 10 are improved.

Specifically, in the embodiment, the first groove is of a shape of a rectangle. Correspondingly, a projection of a side of the inorganic barrier layer 12 facing toward the organic light-emitting material layer 13 on a longitudinal section of the display panel is of a square zigzag shape.

Specifically, in the embodiment, the organic light-emitting material layer 13 disposed in the first groove of the inorganic barrier layer 12 and the organic light-emitting material layer 13 disposed on a convex portion between the adjacent first grooves of the inorganic barrier layer 12 are in a discontinuous distribution, that is, the organic light-emitting material layer 13 disposed on the inorganic barrier layer 12 is discontinuous. The area where the organic light-emitting material layer 13 is located may be unnecessary to be displayed, and the organic light-emitting material layer 13 may be formed in the opening by using an existing evaporation process without changing other processes such as a mask.

It can be understood that in other embodiments, a side of the organic light-emitting material layer 13 facing toward the inorganic barrier layer 12 may be a concave-convex structure corresponding to the inorganic barrier layer 12. That is, the organic light-emitting material layer 13 disposed in the first groove of the inorganic barrier layer 12 and the organic light-emitting material layer 13 disposed on the convex portion between the adjacent first grooves of the inorganic barrier layer 12 are continuous. In an embodiment, the first groove and the protrusion are curved connections, such that the projection of a side of the inorganic barrier layer 12 facing toward the organic light-emitting material layer 13 on the longitudinal section of the display panel 11 is of a wavy shape. The organic light-emitting material layer 13 may be electrically connected to an anode through a connecting hole or by other means, and an organic light-emitting unit may be disposed in each of the openings except the periphery of the pixel defining layer. In this case the area where the organic light-emitting material layer 13 is located can be used for display. That is, in other embodiments, the projection of the side of the inorganic barrier layer 12 facing toward the organic light-emitting material layer 13 on the longitudinal section of the display panel may be of other shapes such as a wave shape, as long as it is provided with a plurality of groove structures spaced apart.

In an embodiment, the surface of the thin film encapsulation structure 14 in contact with the organic light-emitting material layer 13 is provided with a plurality of first protrusions that cooperate with the plurality of first grooves, such that the projection of the surface of the thin film encapsulation structure 14 in contact with the organic light-emitting material layer 13 on the longitudinal section of the display panel 10 is also a concave-convex structure. Specifically, in the embodiment, the projection of the surface of the thin film encapsulation structure 14 in contact with the organic light-emitting material layer 13 on the longitudinal section of the display panel 10 is of a square zigzag shape. It can be understood that in other embodiments, the projection of the surface of the thin film encapsulation structure 14 in contact with the organic light-emitting material layer 13 on the longitudinal section of the display panel 10 may be of a wavy shape.

Further, the thickness of the organic light-emitting material layer 13 in the first groove of the inorganic barrier layer 12 is less than the depth of the first groove, and the thin film encapsulation structure 14 is filled in the first groove and located on the organic light-emitting material layer 13. Thus, the surface of the thin film encapsulation structure 14 in contact with the organic light-emitting material layer 13 has a concave-convex structure corresponding to the inorganic barrier layer 12. And when the organic light-emitting material layer 13 is disconnected, the thin film encapsulation structure 14 and the inorganic barrier layer 12 are in direct contact at the sidewalls of the first groove. Since the bottom layer of the thin film encapsulation structure 14 is an inorganic encapsulation layer, the inorganic encapsulation layer and the inorganic barrier layer 12 is in close contact at the sidewalls in the first groove, so that the encapsulation reliability of the thin film encapsulation structure 14 can be greatly improved.

Further, the inorganic barrier layer 12 is a silicon dioxide film or a silicon nitride film. Specifically, the inorganic barrier layer 12 may be formed by a chemical vapor deposition method.

Further, the inorganic barrier layer 12 has a thickness from 0.5 μm to 1 μm. If the thickness of the inorganic barrier layer 12 is less than 0.5 μm, it is inconvenient to dispose the first groove, which increases the process difficulty. If the thickness of the inorganic barrier layer 12 is greater than 1 μm, it not only affects the hole transport of the organic light-emitting material layer 13, but is also conducive to the normal light emission of the organic light-emitting material layer 13, and reduces the flexibility of the display panel 10 and increases the stress of the display panel 10.

In an embodiment, the display panel 10 includes a display area and a border area surrounding the periphery of the display area, and the part of the openings at the periphery of the pixel defining layer 11 is distributed in the border area. Further, when the display panel 10 is a special-shaped screen to be notched, the border area includes a notch area of the display panel 10. Since the encapsulation structure at the border area including the notch area is easily damaged, the water and oxygen barrier of the display panel 10 is greatly improved by disposing the inorganic barrier layer 12, the organic light-emitting material layer 13 and the thin film encapsulation structure 14 on the border area, which in turn increases encapsulation reliability and service life. Therefore, the display panel 10 is particularly suitable for a special-shaped screen that needs to be notched.

In an embodiment, the thin film encapsulation structure 14 includes a first inorganic layer (not shown), an organic layer (not shown), and a second inorganic layer (not shown) which are sequentially stacked on the pixel defining layer 11.

Further, each of the first inorganic layer and the second inorganic layer is a silicon nitride film, a silicon oxide film, an aluminum oxide film, a silicon oxynitride film or a silicon oxycarbide film.

Further, the organic layer is an acrylate film, an epoxy resin film or a silicone resin film. Further, the organic layer is a polymethyl methacrylate film.

Further, the display panel 10 further includes a base substrate 15, a thin film transistor layer (TFT) 16, a planarization layer (not shown), an anode 17, and an organic light-emitting unit (not shown). The organic light-emitting unit is disposed in each of the openings except the periphery of the pixel defining layer 11. The thin film transistor layer 16 is formed on the base substrate 15, and the planarization layer is formed on the thin film transistor layer 16. The anode 17 is disposed on the planarization layer and at least exposes a part of the planarization layer. The pixel defining layer 11 is formed on the anode 17 and the exposed part of the planarization layer. The opening is disposed in the pixel defining layer 11 and exposes a part of the anode 17.

Further, before the thin film transistor layer 16 is formed on the base substrate 15, other layers such as a buffer layer (not shown) may be formed on the base substrate 15. The buffer layer may be formed on the entire surface of the base substrate 15 or may be formed by being patterned. The buffer layer may be made of a suitable material including a material such as PET, PEN, polyacrylate, and/or polyimide, and be formed as a layered structure in a single layer or a multilayer stack. The buffer layer may also be made of silicon oxide or silicon nitride, or may include a composite layer made of an organic material and/or an inorganic material.

Further, a protection layer (not shown) covering the thin film transistor layer 16 is formed on the thin film transistor layer 16 before the planarization layer is formed on the thin film transistor layer 16. The protection layer may be made of silicon oxide, silicon nitride, and/or other suitable insulating organic or inorganic materials. Further, since the thin film transistor layer 16 has a complicated layer structure, it is generally necessary to form a planarization layer thereon in order to form a sufficiently planar top surface.

Generally, the anode 17 may be made of indium tin oxide (ITO), indium zinc oxide (IZO), zinc oxide (ZnO), indium oxide (In₂O₃), indium gallium oxide (IGO), or aluminum zinc oxide (AZO). It can be understood that there may be generally a plurality of anodes 17, which are distributed in an array, and correspond to the plurality of organic light-emitting units for individually controlling the display of the respective organic light-emitting units, that is, for individually controlling the display of each of the respective pixels.

A display terminal according to an embodiment is further provided, including the above display panel 10, a power module (not shown), a storage module (not shown), and a processing module (not shown).

The power module is configured to supply power to the display screen. The storage module is configured to store media information. The processing module is electrically connected to the display screen, the power module, and the storage module to control the power supply of the power module, and display the media information on the display panel 10.

The display terminal may be a device such as a mobile phone, a television, a tablet, or a computer.

The display terminal adopts the above display panel 10, and has good encapsulation reliability and a long service life.

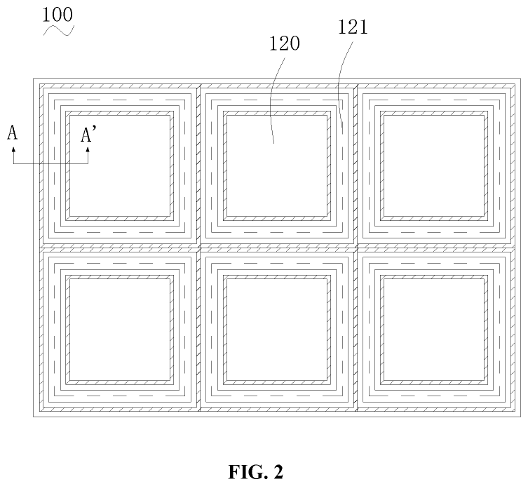

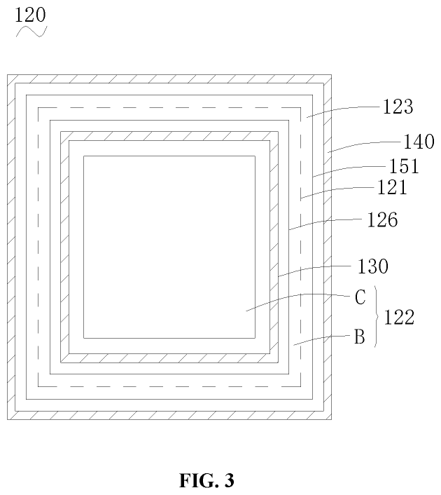

Referring to FIG. 2 to FIG. 3, the display motherboard 100 according to an embodiment includes a bearing substrate (not illustrated) and a plurality of arrangement units 120 formed on the bearing substrate. The bearing substrate may be a glass substrate.

As shown in FIG. 3, the arrangement unit 120 is substantially of a square shape, on which an annular cutting line 121 (indicated by a broken line) is defined. The arrangement unit 120 includes a display panel area 122 located within the cutting line 121, and a cutting area 123 located outside the cutting line 121. Specifically, the display panel area 122 refers to a display panel as an area of a part of the arrangement unit 120 left after cutting along the cutting line 121. The cutting area 123 refers to an outer peripheral area that is removed after cutting along the cutting line 121.

The display panel area 122 includes a display area C located in the middle and a non-display area B surrounding the display area C. The barrier bank 130 is provided at the periphery of the non-display area B. The non-display area B refers to an area of the display panel area 122 other than the display area C. The periphery of the non-display area B refers to an area of the non-display area B close to the cutting line 121. The barrier bank 130 is disposed on the array substrate 124. The barrier bank 130 functions to block the fluid organic material when forming the organic thin film layer of the thin film encapsulation structure.

The cutting area 123 is provided with a stress dispersion bank 140. The stress dispersion bank 140 and the barrier bank 130 are respectively located on both sides of the cutting line 121, and the stress dispersion bank 140 serves to disperse stress during cutting.

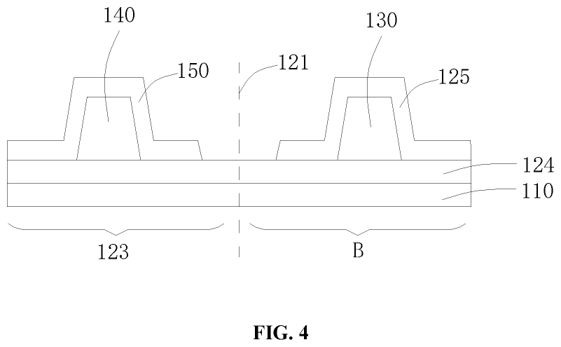

Referring to FIG. 4, the barrier bank 130 and the stress dispersion bank 140 are symmetrically disposed along the cutting line 121 as viewed from the longitudinal section of the display motherboard 100. The “symmetric arrangement” herein means that the positions and sizes of the barrier bank 130 and the stress dispersion bank 140 are axially symmetrically arranged along the cutting line 121. Thus, when the laser cutting is performed, the cutting position is stressed uniformly, the cutting stress can be greatly reduced, and the film encapsulation structure 125 is prevented from being damaged.

The display panel area 122 includes an array substrate 124, an encapsulated device (not shown), and a thin film encapsulation structure 125. The encapsulated device is disposed on the array substrate 124, and the encapsulated device is located in the right side area of the barrier bank 130 in FIG. 4.

The thin film encapsulation structure 125 includes a plurality of film layers encapsulated outside the encapsulated device, and the plurality of film layers include at least one inorganic thin film layer and at least one organic thin film layer. The organic thin film layer is stacked together with the inorganic thin film layer, which is advantageous for obstruct the external water and oxygen layer-by-layer.

In the embodiment shown in FIG. 3, the peripheral line 126 of the thin film encapsulation structure 125 is kept at a certain distance from the cutting line 121, so that the cutting tool (such as laser) can be prevented from cutting the thin film encapsulation structure 125 to damage the thin film encapsulation structure 125 during cutting.

An inorganic layer 150 is formed on the surface of the stress dispersion bank 140 away from the bearing substrate, as shown in FIG. 4. In this configuration, the inorganic layer 150 on the stress dispersion bank 140 corresponds to the thin film encapsulation structure 125 on the barrier bank 130. When laser cutting is performed, it effectively ensures the cutting position is stressed uniformly, and the cutting stress can be greatly reduced, thereby avoiding damaging the thin film encapsulation structure 125.

There may be one layer in the inorganic layer 150, or the inorganic layer 150 may include two or more stacked inorganic sub-layers. Of course, a film layer made of another material in place of the inorganic layer 150 may be formed on the surface of the stress dispersion bank 140 away from the bearing substrate. The inorganic layer 150 may be an aluminum oxide layer, a silicon nitride layer, or an aluminum nitride layer. Since these kinds of inorganic layers are similar in material to the inorganic thin film layer of the thin film encapsulation structure 125, these kinds of inorganic layers can be used for stress dispersion similar to the inorganic thin film layer of the thin film encapsulation structure 125, when the laser cutting is performed. Of course, the material of the inorganic layer 150 is not limited hereto.

In the embodiment shown in FIG. 3, the peripheral line 151 of the inorganic layer 150 is kept at a certain distance from the cutting line 121, so that a symmetrical structure can be formed with the thin film encapsulation structure 125, which is more advantageous for uniform stress during cutting. In an embodiment, the distance between the stress dispersion bank 140 and the cutting line 121 is from about 50 μm to about 500 μm. In this case, the heat radiation and stress during cutting can be transmitted to the stress dispersion bank 140, so the stress dispersion bank 140 can function to disperse the cutting heat radiation and stress, and is also advantageous for maintaining the same magnitude of stress on both sides of the cutting line 121.

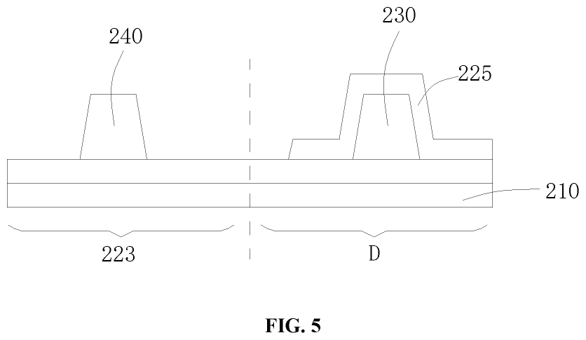

As shown in FIG. 5, in other embodiments, the surface of the stress dispersion bank 240 may not be provided with an inorganic layer. In this case, only the stress dispersion bank 240 is provided in the cutting area 223. Moreover, a barrier bank 230 corresponding to the stress dispersion bank 240 is provided in the non-display area D of the display panel area. A thin film encapsulation structure 225 is formed on the barrier bank 230.

The encapsulated device is an Organic Light-Emitting Diode (OLED). Of course, the encapsulated device can also be other devices.

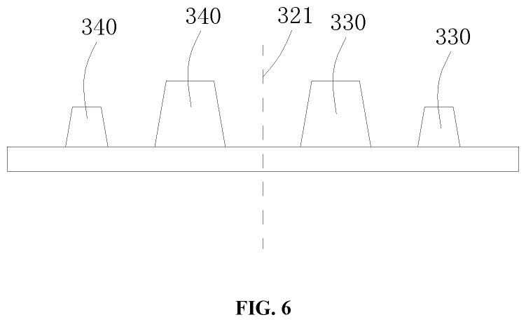

In the above embodiment, the number of the barrier bank 130 and the stress dispersion bank 140 is one. Of course, the number of the barrier bank 130 and the stress dispersion bank 140 is not limited thereto. Referring to FIG. 6, in another embodiment, the number of barrier banks 330 is two, the number of stress dispersion banks 340 is two, and two barrier banks 330 and the two stress dispersion banks 340 are symmetrically arranged along the cutting line 321. When the laser cutting is performed, it is possible to ensure uniform stress at the cutting position, which can greatly reduce the cutting stress and prevent damage of the film encapsulation structure.

Further, it should be noted that the stress dispersion bank in the above embodiment is formed in a circle around an outer periphery of the cutting line, but it is not limited thereto. It is also possible to provide a segment of stress dispersion bank, or a plurality of segments of discontinuous stress dispersion banks at the outer periphery of the cutting line.

Further, the cutting line 121 in the above embodiment includes a regular cutting line such as a screen cutting line. Of course, the cutting line 121 in the above embodiment further includes an irregular cutting line, such as a cutting line of a notch area of a full screen.

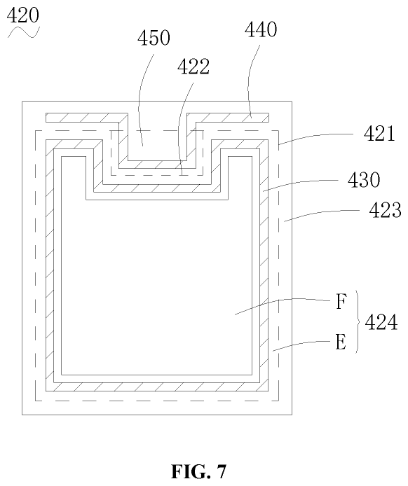

Referring to FIG. 7, in the display motherboard according to another embodiment, the arrangement unit 420 has a cutting line 421. The cutting line 421 includes a U-shaped segment 422, and the stress dispersion bank 440 is disposed close to the U-shaped segment 422. The area enclosed by the U-shaped segment 422 is a notch area 450 of a full screen.

The display panel area 424 includes a non-display area E and a display area F. The periphery of the non-display area E is provided with a barrier bank 430. The cutting area 423 (including the notch area) is provided with a stress dispersion bank 440.

In this embodiment, since the stress dispersion bank 440 is disposed on the periphery of the U-shaped segment 422, the cutting heat radiation and stress generated during the notch cutting at the U-shaped segment 422 are simultaneously transmitted to both sides, thereby reducing the heat radiation and stress applied on the film encapsulation structure, to prevent damage to the thin film encapsulation structure and improve the reliability of the film encapsulation.

Of course, in other embodiments, on the basis of the above embodiments, a circle of stress dispersion banks may be disposed in the cutting area 423, so that the position of the cutting line when the screen is cut is stressed uniformly to prevent damage to the film encapsulation structure, thereby improving the reliability of the film encapsulation.

In addition, it should be noted that the position of the notch on the screen body and the sectional shape of the notch are not limited thereto. For example, it is also possible to provide an annular notch inside the screen body. In this case, a stress dispersion bank for performing stress dispersion may be provided inside the circular notch.

When the display motherboard in the above embodiment is applied, since the barrier bank and the stress dispersion bank are provided on both sides of the cutting line, when the display motherboard is cut, the generated cutting heat radiation and stress are simultaneously transmitted to both sides, thereby reducing the cutting heat radiation and stress applied to the thin film encapsulation structure, to prevent damage to the thin film encapsulation structure, and improve the reliability of the thin film encapsulation. It is beneficial for the application.

All of the technical features in the above embodiments may be employed in arbitrary combinations. For purpose of simplifying the description, not all arbitrary combinations of the technical features in the above embodiments are described. However, as long as such combinations of the technical features are not contradictory, they should be considered as within the scope of the disclosure in the specification.

The above-mentioned embodiments are merely illustrative of several embodiments of the present disclosure, and the description thereof is more specific and detailed, but is not to be construed as limiting the scope of the present disclosure. It should be noted that variations and modifications may be made by those skilled in the art without departing from the scope of the present disclosure. Therefore, the scope of the present disclosure should be determined by the appended claims.

1. A display panel, comprising:
a pixel defining layer, provided with a plurality of openings arranged in an array;
an inorganic barrier layer, disposed in a part of the openings at a periphery of the pixel defining layer, the inorganic barrier layer comprising a first plurality of grooves spaced apart on a side of the inorganic barrier layer;
an organic light-emitting material layer, disposed in the part of the openings having the inorganic barrier layer, and formed on the inorganic barrier layer; and
a thin film encapsulation structure, disposed on the pixel defining layer, the thin film encapsulation structure being filled in the first plurality of grooves and covering the organic light-emitting material layer.

2. The display panel according to claim 1, wherein a surface of the thin film encapsulation structure in contact with the organic light-emitting material layer is provided with a first plurality of protrusions cooperating with the first plurality of grooves.

3. The display panel according to claim 2, wherein the organic light-emitting material layer has a thickness less than a depth of the first plurality of grooves.

4. The display panel according to claim 2, wherein a projection of a side of the inorganic barrier layer facing toward the organic light-emitting material layer on a longitudinal section of the display panel is of a square zigzag shape; and an projection of the surface of the thin film encapsulation structure in contact with the organic light-emitting material layer on the longitudinal section of the display panel is of a square zigzag shape.

5. The display panel according to claim 1, wherein the inorganic barrier layer is formed into a silicon dioxide film or a silicon nitride film.

6. The display panel according to claim 1, wherein the inorganic barrier layer has a thickness from about 0.5 μm to about 1 μm.

7. The display panel according to claim 1, wherein the thin film encapsulation structure comprises a first inorganic layer, an organic layer and a second inorganic layer stacked on the pixel defining layer in sequence.

8. The display panel according to claim 1, wherein the display panel comprises a display area and a border area disposed around the display area, and the part of the openings at the periphery of the pixel defining layer is distributed in the border area.

9. The display panel according to claim 8, wherein the border area comprises a notched area.

10. A display terminal, comprising the display panel according to claim 1.

11. A display motherboard, comprising:
a bearing substrate; and
a plurality of arrangement units arranged on the bearing substrate in an array, each arrangement unit defining an annular cutting line and comprising a display panel area located within the cutting line, and a cutting area located outside the cutting line, wherein the display panel area comprises a display area and a non-display area around the display area, an edge of the non-display area close to the cutting line is provided with a barrier bank, and the cutting area is provided with a stress dispersion bank.

12. The display motherboard according to claim 11, wherein the stress dispersion bank is disposed around the cutting line.

13. The display motherboard according to claim 11, wherein the cutting line comprises a U-shaped segment, and the stress dispersion bank is disposed close to the U-shaped segment.

14. The display motherboard according to claim 11, wherein the barrier bank and the stress dispersion bank are symmetrically disposed along the cutting line.

15. The display motherboard according to claim 11, wherein an inorganic layer is formed on a surface of the stress dispersion bank away from the bearing substrate.

16. The display motherboard according to claim 15, wherein the inorganic layer is an aluminum oxide layer, a silicon nitride layer or an aluminum nitride layer.

17. The display motherboard according to claim 11, wherein the number of the barrier bank is two, the number of the stress dispersion bank is two, and the two barrier banks and the two stress dispersion banks are symmetrically disposed along the cutting line.

18. The display motherboard according to claim 11, wherein a distance between the stress dispersion bank and the cutting line is from about 50 μm to about 500 μm.

19. The display motherboard according to claim 11, wherein the display panel area comprises:
an array substrate;
an encapsulated device disposed on the array substrate; and
a thin film encapsulation structure comprising a plurality of film layers encapsulating outside the encapsulated device, the plurality of film layers comprising at least one inorganic thin film layer and at least one organic thin film layer, the organic thin film layer being stacked together with the inorganic thin film layer.

20. The display motherboard according to claim 19, wherein the encapsulated device is an organic light-emitting diode.
